(19) United States
(12) Patent Application Publication
(10) Pub. No.: US 2025/0038714 A1
(43) Pub. Date: Jan. 30, 2025

(54) BIASING CIRCUIT FOR RADIO FREQUENCY AMPLIFIER

(71) Applicant: MACOM Technology Solutions Holdings, Inc., Lowell, MA (US)

(72) Inventors: Gerard Bouisse, Saint Lys (FR); Jeremy Fisher, Raleigh, NC (US)

(21) Appl. No.: 18/358,394

(22) Filed: Jul. 25, 2023

(51) Int. Cl. H03F 3/195; H03F 1/02; H03F 1/08; H03F 1/34

(52) U.S. Cl. CPC H03F 3/195; H03F 1/0233; H03F 1/086; H03F 1/342

(57) ABSTRACT

A biasing circuit for biasing an output transistor in a radio frequency (RF) amplifier includes a first field-effect transistor (FET) monolithically integrated with the output transistor, the first FET being connected to the output transistor in a current mirror configuration, such that a gate-to-source voltage of the first FET is the same as a gate-to-source voltage of the output transistor, and a drain current in the first FET is matched to a drain current in the output transistor and scaled proportionally according to a size of the first FET relative to a size of the output transistor. The biasing circuit further includes a voltage divider integrated with the first FET and connected to a current source, the voltage divider being configured to generate a voltage that is substantially independent of process, voltage and/or temperature variations for controlling the drain current in the first FET.

### FIELD

The present disclosure relates generally to radio frequency (RF) amplifiers, and, more particularly, to enhanced biasing techniques for RF amplifiers.

### BACKGROUND

Electrical circuits requiring high power handling capability while operating at high frequencies, such as, for example, frequencies greater than about 500 megahertz (MHz), have become increasing more prevalent, particularly in cellular communications and military applications. There currently is demand for semiconductor devices which are capable of both reliably and efficiently operating at radio (including microwave) frequencies while still being capable of handling high power loads.

Gallium nitride (GaN) RF power amplifiers are widely used in communication systems for generating the high power often needed for wireless communications. However, standard RF power amplifiers (e.g., GaN-based high electron mobility transistor amplifiers and silicon-based laterally-diffused metal-oxide semiconductor (LDMOS) power amplifiers) used in many communications applications may exhibit one or more problems, including, for example, requiring an external biasing chip or a dedicated digital-to-analog converter (DAC) to set an appropriate quiescent current in a class AB stage of the amplifier. More particularly, in order to provide thermal compensation of the quiescent current in the amplifier, a specific biasing chip (e.g., AMC7834, commercially available from Texas Instruments Inc.) or a dedicated DAC, in conjunction with a look-up table (LUT), is often used to set and maintain the proper quiescent current in the amplifier despite temperature variations to which the amplifier may be subjected.

### SUMMARY

The present invention, as manifested in one or more embodiments, is directed to novel active biasing circuits and methods which address one or more inherent problems associated with passive decoupling networks for the gate of field-effect transistor (FET)-based RF power amplifiers (e.g., GaN and LDMOS power amplifiers).

In accordance with an embodiment of the present disclosure, a biasing circuit for biasing an output transistor in an RF amplifier includes a first FET monolithically integrated with the output transistor, the first FET including a first source/drain connected to a first voltage source, a gate connected to a gate of the output transistor, and a second source/drain connected to a current source configured to supply a prescribed current to the first FET. The biasing circuit further includes a voltage divider coupled to the current source and configured to control a voltage at the gate of the first FET for setting a direct current (DC) quiescent current in the output transistor.

In accordance with another embodiment of the present disclosure, a biasing circuit for biasing an output transistor in an RF amplifier includes a first FET monolithically integrated with the output transistor, the first FET being connected to the output transistor in a current mirror configuration, such that a gate-to-source voltage of the first FET is the same as a gate-to-source voltage of the output transistor, and a drain current in the first FET is matched to a drain current in the output transistor and scaled proportionally according to a size of the first FET relative to a size of the output transistor. The biasing circuit further includes a voltage divider integrated with the first FET and connected to a current source, the voltage divider being configured to generate a voltage that is substantially independent of process, voltage and/or temperature variations for controlling the drain current in the first FET.

In accordance with yet another embodiment of the present disclosure, a biasing circuit for biasing an output transistor in an RF amplifier includes a first FET monolithically integrated with the output transistor, the first FET being connected to the output transistor in a current mirror configuration, such that a drain current in the first FET is matched to a drain current in the output transistor and scaled proportionally according to a size of the first FET relative to a size of the output transistor. The biasing circuit is configured such that a current in the first FET is substantially independent of process, voltage and/or temperature variations. An impedance presented to a gate of the output transistor by the biasing circuit is ideally zero ohms, but from a more practical standpoint is preferably in a range of about 0 to 20 ohms per millimeter of gate width of the output transistor in the RF amplifier. In other embodiments, the impedance presented to the gate of the output transistor by the biasing circuit may be in a range of about 0 to 10 ohms per millimeter of gate width of the output transistor, or a range of about 0 to 5 ohms per millimeter of gate width of the output transistor, or a range of about 0 to 3 ohms per millimeter of gate width of the output transistor.

Techniques of the present inventive concept can provide substantial beneficial technical effects. By way of example only and without limitation, techniques according to embodiments of the present disclosure may provide one or more of the following advantages, among other benefits:
provides auto-biasing and thermal compensation that is implemented monolithically with the output transistor in the power amplifier;
eliminates the need for an external biasing chip or DAC, used in conjunction with a LUT, to maintain the proper quiescent current in the power amplifier;
provides a very low broadband impedance to the gate of the output transistor of the amplifier, which significantly improves linearization and stability of the power amplifier;
provides ESD protection to the gate of the output transistor in the power amplifier.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 is a simplified schematic diagram depicting at least a portion of an input matching network in an illustrative single-stage RF amplifier;

FIG. 2 is a simplified schematic diagram depicting at least a portion of an input matching network for an output stage or interstage of an illustrative multiple-stage RF amplifier;

FIG. 3 is a simplified schematic diagram depicting at least a portion of an exemplary RF amplifier including an active biasing circuit, according to one or more embodiments of the present invention;

FIG. 4 is a graph depicting an illustrative Monte Carlo simulation using a sample size of 1000 biasing circuits configured as shown in FIG. 3, according to one or more embodiments of the present invention;

FIG. 5 is a Smith chart plot graphically depicting a comparison of the impedance presented to the gate of an RF output transistor as a function of frequency using a conventional biasing scheme and using a biasing scheme according to embodiments of the present invention;

FIG. 6 is a schematic diagram depicting at least a portion of an exemplary RF amplifier including an active biasing circuit that includes negative feedback, according to one or more embodiments of the present invention;

FIG. 7 is a Smith chart plot graphically depicting exemplary impedance presented at the gate of an RF output transistor in the exemplary RF amplifier of FIG. 6 as a function of frequency;

FIG. 8 is a schematic diagram depicting at least a portion of an exemplary RF amplifier including an active biasing circuit that includes negative feedback and a cascode low-impedance path, according to one or more embodiments of the present invention;

FIG. 9 is a Smith chart plot graphically depicting the impedance presented to the gate of an RF output transistor as a function of frequency using the illustrative biasing circuit shown in FIG. 8, according to one or more embodiments of the present invention;

FIGS. 10A through 10C are graphs conceptually depicting the impact of the gate width of the transistors used in the biasing circuit shown in FIG. 8 on current consumption and real and imaginary baseband impedance presented to the RF output transistor to be biased, according to one or more embodiments of the present invention;

FIGS. 11A and 11B are graphs plotting exemplary Monte Carlo simulation results showing the variation in drain current of the bias FET in the biasing circuit over 1000 samples, according to one or more embodiments of the present invention;

FIG. 12 is a schematic diagram depicting at least a portion of an output stage of an exemplary RF amplifier without electrostatic discharge (ESD) protection; and

FIG. 13 is a schematic diagram depicting at least a portion of an exemplary RF amplifier that includes an active biasing circuit configured to provide ESD protection, according to one or more embodiments of the present invention.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION OF EMBODIMENTS

Principles of the present invention, as manifested in one or more embodiments thereof, may be described herein in the context of an RF power amplifier system, and more specifically to embodiments of an active biasing circuit configured to be monolithically integrated with the output transistor of an RF amplifier, which may be suitable for use in a wireless communications environment, among other beneficial applications. It is to be appreciated, however, that the invention is not limited to the specific devices, circuits, systems and/or methods illustratively shown and described herein. Rather, it will become apparent to those skilled in the art given the teachings herein that numerous modifications to the embodiments shown are contemplated and are within the scope of the present inventive concept. That is, no limitations with respect to the embodiments shown and described herein are intended or should be inferred.

As will be discussed in detail herein, it has been discovered that conventional passive decoupling networks included in RF power amplifiers may have inherent problems associated therewith, including the inability to maintain a proper quiescent bias current in the amplifier over variations in process, voltage and/or temperature (PVT) conditions to which the amplifier may be subjected. Consequently, external biasing circuitry (e.g., AMC7834 from Texas Instruments Inc.) is often employed to set the proper quiescent current in the amplifier and provide temperature compensation for maintaining the set quiescent current over variations in temperature. This external biasing circuitry adds significant cost to the power amplifier, which is undesirable. Furthermore, the biasing circuitry typically presents a baseband impedance at the gate of an output transistor in the amplifier that may exhibit various resonances, due primarily to decoupling capacitors employed in the biasing circuitry, which act as resonators in the frequency band(s) of interest. These resonances are problematic, particularly with respect to linearization of the amplifier, in that they require the addition of series resistance in order to maintain stability (i.e., avoid oscillations) of the amplifier. This series resistance requirement prevents the realization of an “ideal” power amplifier design, where direct current (DC) and baseband impedance should be zero. The resonances can also degrade video bandwidth (VBW) performance of the amplifier. Additionally, conventional passive decoupling networks or external biasing circuitry included in the RF power amplifiers generally do not provide ESD protection to the amplifier.

Pursuant to embodiments of the present invention, biasing circuits are provided for use in an RF power amplifier that are configured to maintain a desired quiescent current in the amplifier despite PVT variations, thereby significantly improving linearization, stability and VBW performance in the amplifier, among other advantages. For example, such biasing circuits, due at least in part to the low impedance presented to the gate of an RF output transistor in the amplifier, may additionally provide beneficial ESD protection for the amplifier. Furthermore, embodiments of the invention may eliminate the need for external biasing circuitry by monolithically integrating the biasing circuit with the output transistor (e.g., power FET) in the RF power amplifier. Being integrated in close proximity to the output transistor, the biasing circuits according to aspects of the present inventive concept can beneficially provide more accurate temperature compensation/tracking in the power amplifier, thus further enhancing linearity and stability of the power amplifier.

A biasing circuit for biasing an output transistor in an RF amplifier, according to one or more embodiments of the invention, includes a first FET monolithically integrated with the output transistor, the first FET including a first source/drain connected to a first voltage source (which may be ground), a gate connected to a gate of the output transistor, and a second source/drain connected to a current source configured to supply a prescribed current to the first FET. The bias circuit further includes a voltage divider coupled to the current source and configured to control a voltage at the gate of the first FET for setting a DC quiescent current in the output transistor. In one or more embodiments, the first source/drain of the first FET is connected to a first source/drain of the output transistor, so that the first FET and the output FET are connected in a current mirror configuration. In some embodiments, the voltage divider may include a first resistor connected between the second source/drain and the gate of the first FET, and a second resistor connected between the gate of the first FET and a second voltage source. In one or more embodiments, an impedance presented to the gate of the output transistor by the biasing circuit is configured to be ideally zero ohms, but from a more practical standpoint is configured to be in a range of about 0 to 20 ohms per millimeter of gate width of the output transistor in the RF amplifier. In other embodiments, the impedance presented to the gate of the output transistor by the biasing circuit may be configured to be in a range of about 0 to 10 ohms per millimeter of gate width of the output transistor, or in a range of about 0 to 5 ohms per millimeter of gate width of the output transistor, or in a range of about 0 to 3 ohms per millimeter of gate width of the output transistor.

A biasing circuit for biasing an output transistor in an RF amplifier, according to one or more embodiments of the invention, includes a first FET monolithically integrated with the output transistor, the first FET being connected to the output transistor in a current mirror configuration, such that a gate-to-source voltage of the first FET is the same as a gate-to-source voltage of the output transistor, and a drain current in the first FET is matched to a drain current in the output transistor and scaled proportionally according to a size of the first FET relative to a size of the output transistor. The biasing circuit further includes a voltage divider integrated with the first FET and connected to a current source, the voltage divider being configured to generate a voltage that is substantially independent of temperature variations for controlling the drain current in the first FET.

A biasing circuit for biasing an output transistor in an RF amplifier, according to one or more embodiments of the invention, includes a first FET monolithically integrated with the output transistor, the first FET being connected to the output transistor in a current mirror configuration, such that a drain current in the first FET is matched to a drain current in the output transistor and scaled proportionally according to a size of the first FET relative to a size of the output transistor. The biasing circuit is configured such that the drain current in the first FET is substantially independent of process, voltage and/or temperature variations, and wherein an impedance presented to a gate of the output transistor by the biasing circuit is configured to be ideally zero ohms, but from a more practical standpoint is configured to be in a range of about 0 to 20 ohms per millimeter of gate width of the output transistor in the RF amplifier. In other embodiments, the impedance presented to the gate of the output transistor by the biasing circuit may be configured to be in a range of about 0 to 10 ohms per millimeter of gate width of the output transistor, or in a range of about 0 to 5 ohms per millimeter of gate width of the output transistor, or in a range of about 0 to 3 ohms per millimeter of gate width of the output transistor.

RF transistor amplifiers according to embodiments of the present invention may be designed to operate in a wide variety of different frequency bands. In some embodiments, for example, the RF transistor amplifiers may be configured to operate at frequencies greater than 1 gigahertz (GHz). In other embodiments, these RF transistor amplifiers may be configured to operate at frequencies greater than 2.5 GHZ. In still other embodiments, the RF transistor amplifiers may be configured to operate at frequencies greater than 3.1 GHz. In yet additional embodiments, these RF transistor amplifiers may be configured to operate at frequencies greater than 5 GHz. In some embodiments, these RF transistor amplifiers may be configured to operate in at least one of the 0.6-1.0 GHz, 1.4-2.7 GHZ, 3.1-4.2 GHZ, 5.1-5.8 GHz, 12-18 GHz, 18-27 GHz, 27-40 GHz or 40-75 GHz frequency bands or sub-portions thereof.

An efficient power amplifier contributes to the development of high data rate cellular communications systems, among other beneficial applications. Such efficiency can be achieved by developing linear power amplifiers to transmit signals. Distortions due to the nonlinearity of power amplifiers can be minimized using several linearization techniques. Linearization is a parameter often used to characterize the performance of a power amplifier, and generally refers to the maximum modulating frequency that can be used by the amplifier within a prescribed frequency band. As cellular bit (data) rates are increased, it has become more challenging to design an RF power amplifier capable of satisfying the higher VBW performance criteria. This may be particularly true with respect to Doherty amplifiers.

In cellular communications systems (which may be referred to herein as cellular infrastructure or “CIFR” applications), as well as many other radio communication systems where higher power levels and higher efficiency are required (e.g., higher peak-to-average power ratio), Doherty RF power amplifiers are often used. As is known in the art, a Doherty amplifier circuit includes first and second (or more) power-combined amplifiers. The first amplifier is referred to as a “main” or “carrier” amplifier and the second amplifier is referred to as a “peaking” or “auxiliary” amplifier. The two (or more) amplifiers may be biased differently. For example, the main amplifier may comprise a Class AB or a Class B amplifier while the peaking amplifier may be a Class C amplifier in one common Doherty amplifier implementation. In either case, however, by setting and maintaining a proper quiescent bias current in the power amplifier despite PVT variations, the power amplifier can advantageously achieve enhanced linearity and stability, and therefore improved VBW performance.

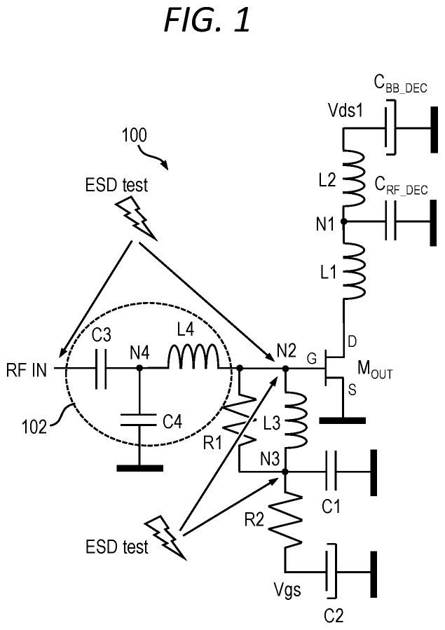

FIG. 1 is a simplified schematic diagram depicting at least a portion of an input matching network in an illustrative single-stage RF amplifier 100. The RF amplifier 100 may include a power field-effect transistor (FET), M_{OUT}, having a drain (D) connected to a first terminal of a first matching inductor, L1, a source(S) connected to ground (or another voltage source), and a gate (G) adapted to receive an RF input signal, RF_IN, supplied to the amplifier. It is to be appreciated that, because a FET device may be symmetrical by nature, and thus bidirectional, the assignment of source and drain designations in the FET device is essentially arbitrary. Therefore, the source and drain of the FET transistor M_{OUT} may be referred to herein generally as first and second source/drain, respectively, where “source/drain” in this context denotes a source or a drain of the FET transistor.

With continued reference to FIG. 1, the RF amplifier 100 further includes a second matching inductor, L2, having a first terminal connected to a second terminal of the first matching inductor L1 at a first node N1, and having a second terminal forming a drain-source node, Vds1, of the amplifier. An RF decoupling capacitor, C_{RF_DEC}, may be connected between node N1 and ground, and a baseband decoupling capacitor, C_{BB_DEC}, may be connected between node Vds1 and ground. The values of the RF and baseband decoupling capacitors C_{RF_DEC} and C_{BB_DEC} are preferably selected to shunt signals in the RF and baseband frequency ranges, respectively. In some embodiments, the RF decoupling capacitor C_{RF_DEC} may have a value on the order of about tens of picofarad (pF) and the baseband decoupling capacitor C_{BB_DEC} may have a value of about one to tens of microfarad (μF), although embodiments of the invention are not limited to any specific decoupling capacitor values.

A gate biasing circuit in the RF amplifier 100 may include a first resistor R1 and a second resistor, R2, connected in series between the gate of transistor M_{OUT} and a bias voltage source, Vgs. Specifically, a first terminal of the resistor R1 may be connected to the gate of the transistor M_{OUT} at a second node, N2, a second terminal of the resistor R1 may be connected to a first terminal of the resistor R2 at a third node, N3, and a second terminal of the resistor R2 may be connected to the bias voltage source Vgs. A bypass inductor, L3, may be connected in parallel across resistor R1 to form a parallel resistor-inductor (RL) circuit; that is, bypass inductor L3 may be connected between the gate of the transistor MOUT and node N3. The bypass inductor L3 may be selected so that the resistance of the parallel RL circuit (comprising resistor R1 and inductor L3) at baseband frequencies (e.g., DC to about 300 MHz) is close to zero ohms (52), but becomes essentially equal to the value of resistor R1 at RF frequencies of about 3.5 GHz or greater.

The gate biasing circuit may further include decoupling capacitors, such as a bias RF decoupling capacitor, C1, connected between node N3 and ground (or another voltage source), and a bias baseband decoupling capacitor, C2, connected between the bias voltage source Vgs and ground. The values of the bias RF and baseband decoupling capacitors C1 and C2 are preferably selected to shunt signals in the RF and baseband frequency ranges, respectively. In some embodiments, the bias RF decoupling capacitor C1 may have a value on the order of about tens of pF and the bias baseband decoupling capacitor C2 may have a value of about one to tens of μF, although embodiments of the invention are not limited to any specific decoupling capacitor values.

One problem with this standard current biasing arrangement is that the impedance loading the gate of the output transistor M_{OUT} becomes significantly large for low frequencies. This is due primarily to the fact that the AC ground relates to the decoupling capacitors, each of which has an impedance Z_{C}=1/@C, where Z_{C} is the impedance of the capacitor, ω is the angular frequency (given by ω=2πf, where f is the frequency of the signal), and C is the capacitance of the capacitor.

The RF amplifier 100 may further include an impedance matching network 102 connected between an input of the RF amplifier 100, adapted to receive the input signal RF IN, and the gate of the transistor M_{OUT}. More particularly, the impedance matching network 102 may comprise a series inductor, L4, a series capacitor, C3, and a shunt capacitor, C4. The series inductor L4 may be connected between the gate of transistor M_{OUT} at node N2 and a fourth node, N4, the series capacitor C3 may be connected between node N4 and the input of the RF amplifier 100, and the shunt capacitor C4 may be connected between node N4 and ground (or a voltage source acting as an RF virtual ground).

Conventionally, the first and second matching inductors L1, L2, the RF and baseband decoupling capacitors C_{RF_DEC}, C_{BB_DEC}, the second bias resistor R2 and the bias baseband decoupling capacitor C2, may be implemented using surface mount devices (SMDs) residing on an external chip with respect to the RF amplifier 100. Likewise, the bias resistor R1, the bypass inductor L3, the bias RF decoupling capacitor C1 and the elements of the impedance matching network 102 may be implemented as external components in some embodiments; in other embodiments, these components may be integrated on the chip with the RF amplifier 100. However, even if these components are integrated with the RF amplifier 100, the resistors R1 and R2 forming the primary DC biasing circuit will not be matched to one another, at least in terms of absolute resistance values and temperature coefficients. Consequently, this bias voltage may be sensitive to PVT variations, which could potentially lead to linearization difficulties in the amplifier 100. Moreover, the use of external components in the input matching stage of the RF amplifier 100 leaves the gate of the transistor M_{OUT} vulnerable to ESD events.

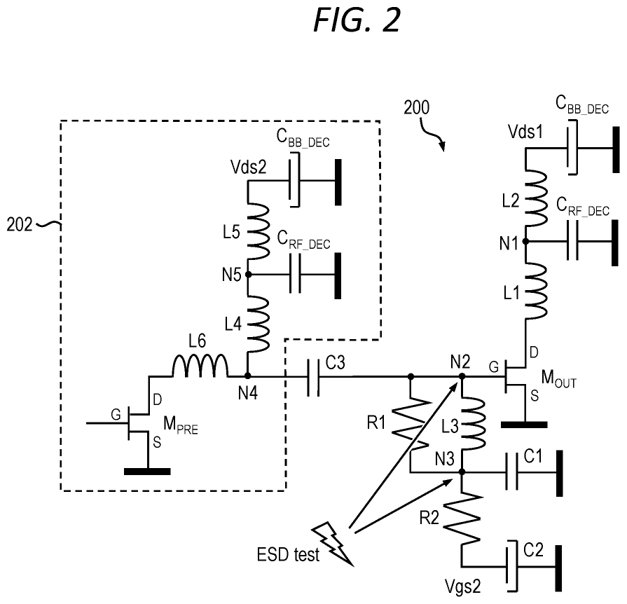

The above-noted problems that are inherent in conventional biasing schemes used for single-stage RF amplifiers are similarly present in a multiple-stage RF amplifier. FIG. 2 is a simplified schematic diagram depicting at least a portion of an input matching network for an output stage or interstage of an illustrative multiple-stage RF amplifier 200. The multiple-stage RF amplifier 200 may include an output stage (or interstage) that is essentially the same as the exemplary output stage in the RF amplifier 100 shown in FIG. 1, comprising output FET device M_{OUT}, first and second matching inductors L1, L2, RF and baseband decoupling capacitors C_{RF_DEC}, C_{BB_DEC}, and biasing circuitry (resistors R1, R2, bypass inductor L3, and bias decoupling capacitors C1, C2).

The illustrative multiple-stage RF amplifier 200, in this example, may not necessarily include an impedance matching network (e.g., 102 in FIG. 1), but may include a series DC blocking capacitor C3 connected between the gate of the output transistor M_{OUT} at node N2 and the input of the output stage at node N4, to which an output of a preceding amplifier stage 202 is coupled. The DC blocking capacitor C3 allows the output stage and the preceding amplifier stage 202 to be biased at different DC quiescent operating points.

The preceding amplifier stage 202 in the RF amplifier 200 may comprise a FET device, M_{PRE}, having a drain connected to a first terminal of an impedance matching inductor, L6. A second terminal of the inductor L6 may be connected to the series DC blocking capacitor C3 at node N4. A source of the transistor M_{PRE} may be connected to ground (or another voltage source, such as VSS), and a gate of the transistor M_{PRE} is adapted to receive an input RF signal supplied to the RF amplifier 200 from an external source or from another preceding amplifier stage (not explicitly shown, but implied).

The preceding amplifier stage 202 in the RF amplifier 200 may further include a first matching inductor, L4, having a first terminal coupled to the series inductor L6 at node N4, and a second terminal connected to a first terminal of a second matching inductor, L5, at a fifth node, N5. A second terminal of the second matching inductor L5 forms a second drain-source node, Vds2. An RF decoupling capacitor, C_{RF_DEC}, may be connected between node N5 and ground, and a baseband decoupling capacitor, C_{BB_DEC}, may be connected between node Vds2 and ground in the preceding amplifier stage 202. Like the RF and baseband decoupling capacitors in the output stage of the RF amplifier 200, the values of the RF and baseband decoupling capacitors C_{RF_DEC} and C_{BB_DEC} in the preceding amplifier stage 202 are preferably selected to shunt signals in the RF and baseband frequency ranges, respectively. In some embodiments, the RF decoupling capacitor C_{RF_DEC} may have a value on the order of about tens of pF and the baseband decoupling capacitor C_{BB_DEC} may have a value of about one to tens of μF, although embodiments of the invention are not limited to any specific decoupling capacitor values.

As was the case for the single-stage RF amplifier 100 shown in FIG. 1, the first and second matching inductors L1, L2, the RF and baseband decoupling capacitors C_{RF_DEC}, C_{BB_DEC}, the second bias resistor R2 and the bias baseband decoupling capacitor C2 in the output stage of the multiple-stage RF amplifier 200 of FIG. 1, as well as the first and second matching inductors L5, L6, and the RF and baseband decoupling capacitors C_{RF_DEC}, C_{BB_DEC} in the preceding amplifier stage 202, may be implemented using surface mount devices (SMDs) residing on an external chip with respect to the RF amplifier 200. Likewise, the bias resistor R1, the bypass inductor L3, the bias RF decoupling capacitor C1, the series DC blocking capacitor C3, and matching inductors L4, L5, may be implemented as external components in some embodiments; in other embodiments, these components may be integrated on the chip with the RF amplifier 200. However, even if these components are integrated with the RF amplifier 200, the resistors R1 and R2 forming the primary biasing circuit for setting the DC quiescent current in the output transistor M_{OUT} will not be matched to one another, at least in terms of absolute resistance values and temperature coefficients. Consequently, this bias voltage may be sensitive to PVT variations, which could potentially lead to linearization difficulties in the amplifier 200. Moreover, the use of external components in the input matching stage of the RF amplifier 200 leaves the gate of the transistor M_{OUT} vulnerable to ESD events.

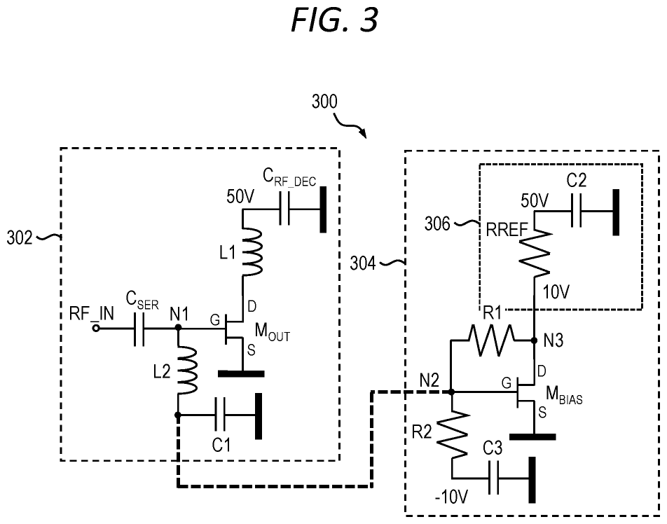

FIG. 3 is a simplified schematic diagram depicting at least a portion of an exemplary RF amplifier 300 including an active biasing circuit, according to one or more embodiments of the invention. With reference to FIG. 3, the RF amplifier 300 may include an output stage 302 and an active biasing circuit 304 configured to be coupled to and monolithically integrated with an output transistor M_{OUT} of the output stage 302.

The output stage 302 may be implemented in a manner consistent with the output stage of the RF amplifier 100 shown in FIG. 1. Specifically, the output stage 302 may include an RF output FET (e.g., GaN, LDMOS, etc.), M_{OUT}, having a drain connected to a first voltage source (e.g., 50V supply) through a series matching inductor, L1, and a source connected to ground (or another voltage source, such as VSS). An RF decoupling capacitor, C_{RF_DEC}, may be connected between the voltage source and ground (or another voltage source, such as VSS). The value of the RF decoupling capacitor C_{RF_DEC} is preferably selected to shunt signals in the RF frequency range (e.g., tens of pF). A gate of the RF output transistor M_{OUT} may be configured to receive an RF input signal, RF_IN, supplied to the amplifier 300 through a series DC blocking capacitor, CSER, connected to the gate of the RF output transistor M_{OUT} at a first node, N1.

The biasing circuit 304 in the RF amplifier 300 may include a bias FET, M_{BIAS}, having a drain connected to a current source 306, and a source connected to ground (or another voltage source, such as VSS). A gate of the bias transistor M_{BIAS} at a second node, N2, may be connected to the gate of the RF output transistor M_{OUT} through a series inductor, L2. Thus, in one or more embodiments, the bias transistor M_{BIAS} and the RF output transistor M_{OUT} are effectively connected in a current mirror configuration, such that the DC gate-to-source voltage (Vgs) of the bias transistor M_{BIAS} will be essentially the same as the Vgs of the RF output transistor M_{OUT}. An RF decoupling capacitor, C1, may be connected between the gate of the bias transistor M_{BIAS} at node N2 and ground and configured to shunt RF signals that may be present on the gate connection.

In this current mirror configuration, with the Vgs of the bias transistor M_{BIAS} being the replicated as the Vgs of the RF output transistor M_{OUT}, a drain current in the RF output transistor M_{OUT} will be matched to a reference drain current in the bias transistor M_{BIAS}, scaled in proportion to a channel width-to-length ratio (W/L) of the bias transistor M_{BIAS} relative to the channel W/L of the RF output transistor M_{OUT}, at least to a first order (e.g., ignoring the effects of drain voltage modulation, etc.). In one or more embodiments, the channel W/L of the RF output transistor M_{OUT} may be configured to be about ten times larger than the channel W/L of the bias transistor M_{BIAS}, so that the drain current of the RF output transistor M_{OUT} will be about ten times larger than the drain current of the bias transistor M_{BIAS}.

For enhanced matching, the bias transistor M_{BIAS} may be configured to be in close proximity to the RF output transistor M_{OUT}, such that the bias transistor is thermally coupled with the RF output transistor and is formed in semiconductor material having similar electrical properties. For example, in one or more embodiments, the RF output transistor M_{OUT} can be configured having a multi-fingered gate structure, and the bias transistor M_{BIAS} may be configured having one or more gate fingers embedded within (or among) the gate fingers of the output transistor M_{OUT}. In this manner, current-voltage (I-V) curves associated with the RF output transistor M_{OUT} will be essentially the same as the I-V curves for the bias transistor M_{BIAS}, and process and/or temperature variations to which the output transistor M_{OUT} is subjected will closely track process and/or temperature variations to which the bias transistor M_{BIAS} is subjected.

The current source 306 for establishing the reference drain current in the bias transistor M_{BIAS} may be implemented using a precision reference resistor, RREF, having a first terminal connected to the drain of the bias transistor M_{BIAS} at a third node, N3, and a second terminal connected to the first voltage source, which may be a 50 volt supply in some embodiments, although embodiments of the invention are not limited to any specific voltage of the first voltage source. More particularly, in one or more embodiments, the reference resistor RREF may be implemented using a precision external resistor (e.g., thin film, etc.) having a tolerance of about one percent, although embodiments of the invention are not limited to such a precision value. Optionally, an RF decoupling capacitor, C2, may be connected between the first voltage source and ground. The value of the RF decoupling capacitor C2 is preferably selected to shunt signals in the RF frequency range (e.g., tens of pF).

The biasing circuit 304 includes a voltage divider which may be implemented using a first resistor, R1, and a second resistor, R2. For voltage and temperature tracking purposes, the first and second resistors R1, R2 may be formed of the same material and may be located in close proximity relative to one another. The first resistor R1 may be configured having a first terminal connected to the drain of the bias transistor M_{BIAS} at node N3 and a second terminal connected to the gate of the bias transistor M_{BIAS} at node N2. The second resistor R2 may be configured having a first terminal connected to the gate of the bias transistor M_{BIAS} at node N2 and a second terminal connected to a second voltage source, which may be a −10 volt supply, although embodiments of the invention are not limited to any specific voltage of the second voltage source. Optionally, an RF decoupling capacitor, C3, may be connected between the second voltage source and ground. The value of the RF decoupling capacitor C3 is preferably selected to shunt signals in the RF frequency range (e.g., tens of pF). The voltage divider may be configured to control a voltage at the gate of the bias transistor M_{BIAS} at node N2 for setting a quiescent operating point of the output transistor M_{OUT}.

Resistance values of the reference resistor RREF and the first and second resistors R1, R2 forming the voltage divider may be selected to establish a prescribed drain current in the bias transistor M_{BIAS}, which, using the current mirror configuration of the bias and output transistors, will establish a corresponding quiescent current in the RF output transistor M_{OUT}. The first and second resistors R1, R2 may be integrated with the output stage 302. Since the first and second resistors R1, R2 are preferably used as a voltage divider, a ratio of their respective resistance values is used to set a gate voltage of the bias transistor M_{BIAS} at node N2. Accordingly, the first and second resistors R1, R2 do not need to be matched, in terms of absolute resistance value or temperature coefficient, to the reference resistor RREF, and furthermore do not require the same level of precision as the reference resistor RREF; that is, resistors R1 and R2 may be implemented using a much lower level of precision (e.g., +10%) compared to the reference resistor RREF. Additionally, assuming the first and second resistors R1, R2 are formed of the same material and in close proximity to one another, process and/or temperature tracking between the two resistors should be closely matched.

It is to be appreciated that the current source may be configured such that the drain of the bias transistor M_{BIAS} does not receive the full voltage of the first voltage source. For example, in some embodiments, the first voltage source may be a 50V supply and the reference resistor RREF in the current source 306 may be selected so that only about 10V is seen at the drain of the bias transistor M_{BIAS} at node N3. This eliminates the necessity of using a power FET device for the bias transistor, unlike the RF output transistor M_{OUT}, which may receive the entire voltage amount (e.g., 50V) of the first voltage source at its drain.

Thus, with continued reference to FIG. 3, a biasing circuit for biasing an output transistor in an RF amplifier, according to one or more embodiments of the invention, includes a first FET (M_{BIAS}) monolithically integrated with the output transistor (M_{OUT}), the first FET including a first source/drain(S) connected to a first voltage source (which may be ground), a gate (G) connected to a gate of the output transistor (M_{OUT}), and a second source/drain (D) connected to a current source (306) configured to supply a prescribed current to the first FET. The bias circuit further includes a voltage divider coupled to the current source and configured to control a voltage at the gate of the first FET for setting a DC quiescent current in the output transistor (M_{OUT}). In some embodiments, the voltage divider may include a first resistor (R1) connected between the second source/drain and the gate of the first FET (M_{BIAS}), and a second resistor (R2) connected between the gate of the first FET and a second voltage source. In one or more embodiments, an impedance presented to the gate of the output transistor (M_{OUT}) is configured to be ideally zero ohms, but from a more practical standpoint is configured to be in a range of about 0 to 20 ohms per millimeter of gate width of the output transistor M_{OUT}. In other embodiments, the impedance presented to the gate of the output transistor by the biasing circuit may be configured to be in a range of about 0 to 10 ohms per millimeter of gate width of the output transistor, or in a range of about 0 to 5 ohms per millimeter of gate width of the output transistor, or in a range of about 0 to 3 ohms per millimeter of gate width of the output transistor. In some embodiments, the gate of the first FET (M_{BIAS}) is connected to the gate of the output transistor (M_{OUT}) in the RF amplifier through a series inductor (L2). In some embodiments, the current source comprises: an external resistor connected between the voltage divider and a second voltage source; and a decoupling capacitor connected between the first and second voltage sources, the decoupling capacitor being configured to shunt signals in a prescribed RF frequency range. In one or more embodiments, the first FET (M_{BIAS}) is formed as at least one finger among a plurality of fingers of the output transistor (M_{OUT}).

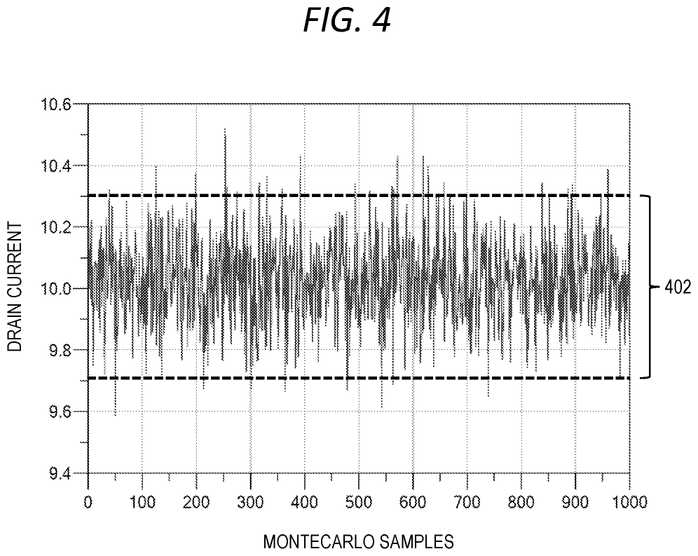

By way of example only and without loss of generality, FIG. 4 is a graph depicting an illustrative Monte Carlo simulation using a sample size of 1000 biasing circuits configured as shown in FIG. 3. Exemplary component values used for generating the simulation depicted in FIG. 4 are shown in the table below. It is to be understood that embodiments of the invention are not limited to such component values. A load resistance at the drain of the RF output transistor M_{OUT} (forming an output of the RF amplifier 300) was assumed to be 50 ohms.

| | | |
|---|---|---|
| RREF | 26.2K | ohms |
| R1 | 127K | ohms |
| R2 | 73.4K | ohms |

With reference to FIG. 4, using a precision value of the reference resistor RREF of ±1% and a precision value of the first and second resistors R1, R2 forming the voltage divider in the biasing circuit 304 of ±10%, the quiescent current in the RF output transistor M_{OUT} over a sample size of 1000 biasing circuits was found to be tightly controlled in a range 402 of about 10 mA±0.3 mA (or ±3%). Although an absolute tolerance of each of the resistors R1 and R2 in the voltage divider may be ±10%, it is a ratio of these resistors that is used to set the gate voltage of the bias FET M_{BIAS}, which tends to exhibit greater accuracy against PVT variations.

As previously stated, a size (i.e., W/L ratio) of the bias transistor M_{BIAS} can be scaled to be much smaller than the size of the RF output transistor M_{OUT} (e.g., ten times smaller). Additionally, by operating the bias transistor M_{BIAS} under much lower drain voltage (e.g., about 10 V compared to about 50 V), the drain current drawn by the bias transistor M_{BIAS} will be much lower compared to the quiescent current of the RF output transistor M_{OUT}. Both of these considerations beneficially enable the current consumption of the biasing circuit 304 to be negligible compared to the quiescent current in the output stage 302 of the RF amplifier 300.

An advantage of the configuration of the biasing circuit 304 shown in FIG. 3 is that it eliminates the need for external baseband decoupling capacitors which are typically implemented as SMD elements. Consequently, undesirable resonances associated with these SMD decoupling capacitors may also be eliminated. This is achieved primarily through the use of an active biasing circuit 304, which beneficially presents an impedance at the gate of the RF output transistor M_{OUT} that is significantly lower compared to conventional biasing circuit arrangements.

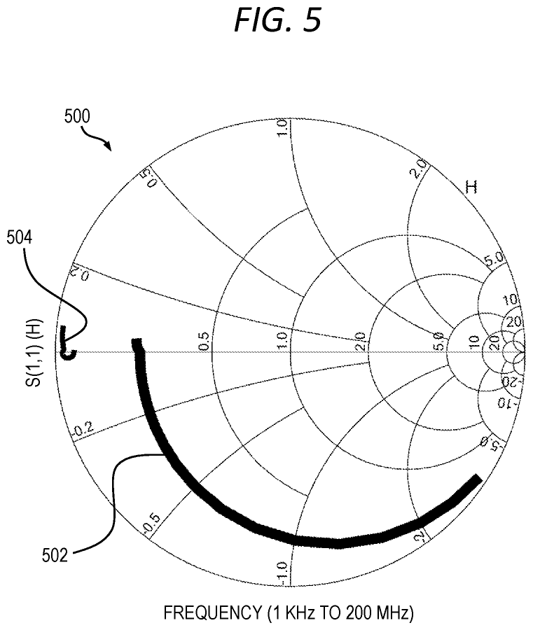

FIG. 5 is a Smith chart plot 500 graphically depicting a comparison of the impedance presented to the gate of an RF transistor as a function of frequency using a conventional biasing scheme and using a biasing scheme according to embodiments of the invention. Waveform 502 represents the impedance presented to the gate of the RF transistor through a conventional biasing arrangement using SMDs (e.g., in the RF amplifier 100 shown in FIG. 1); waveform 504 represents the impedance presented to the gate of the RF transistor through a biasing circuit according to embodiments of the invention (e.g., in the RF amplifier 300 shown in FIG. 3). As evident from FIG. 5, the impedance presented to the gate of the RF transistor using a conventional biasing circuit varies widely with frequency (waveform 502), while the impedance presented to the gate of the RF transistor using the biasing circuit according to embodiments of the inventive concept remains nearly an ideal short circuit (zero ohms) from about 1 KHz to 200 MHz (waveform 504).

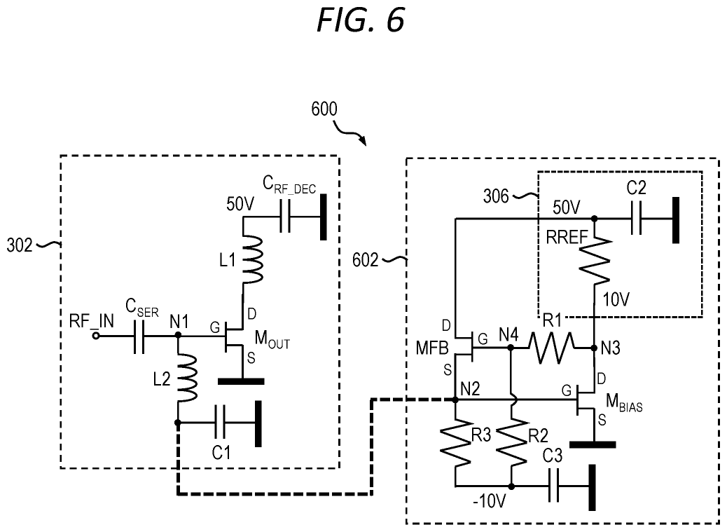

An impedance presented to the gate of the RF output transistor M_{OUT} in the RF amplifier 300 can be reduced even further by modifying the biasing circuit to incorporate negative feedback, according to some embodiments. FIG. 6 is a schematic diagram depicting at least a portion of an exemplary RF amplifier 600 including an active biasing circuit that includes negative feedback, according to one or more embodiments of the invention. Referring now to FIG. 6, the RF amplifier 600 includes an output stage 302, which may be implemented in the same manner as previously described and shown in FIG. 3, and an active biasing circuit 602 configured to be coupled to and monolithically integrated with the output transistor M_{OUT} of the output stage 302.

The biasing circuit 602 is similar to the biasing circuit 304 shown in FIG. 3, except for the inclusion of a negative feedback circuit implemented using a second FET device connected in a source follower configuration. A source follower circuit may be used to convert a high impedance input to a low impedance output. This can be accomplished by using a FET as the input device, with the source of the FET connected to the input signal and the drain connected to the output. The gate of the FET is connected to a bias voltage, which controls the current flowing through the FET. The output impedance of the source follower circuit is determined by the drain-source on-resistance (R_{DS_ON}) of the FET, which is typically very low. This allows the source follower circuit to drive a low impedance load while maintaining a high input impedance.

With continued reference to FIG. 6, the biasing circuit 602 includes bias FET, M_{BIAS}, having a drain connected to a current source 306 at node N3, and a source connected to ground (or another voltage source, such as VSS). As in the illustrative biasing circuit 304 of FIG. 3, the current source 306 for establishing the reference drain current in the bias transistor M_{BIAS} may be implemented using a precision reference resistor, RREF, having a first terminal connected to the drain of the bias transistor M_{BIAS} at node N3, and a second terminal connected to the first voltage source, which may be a 50 volt supply in some embodiments. The reference resistor RREF may be implemented using a precision external resistor (e.g., thin film, etc.) having a tolerance of about one percent, although embodiments of the invention are not limited thereto. An RF decoupling capacitor C2 may be optionally connected between the first voltage source and ground and configured to shunt RF signal components that may be introduced into the first voltage source.

The biasing circuit 602 may further include a feedback FET, MFB, connected in a negative feedback configuration with the bias transistor M_{BIAS}. More particularly, the feedback transistor MFB may include a drain connected to the first voltage source, a source connected to the gate of the bias transistor M_{BIAS} at node N2, and a gate connected to a voltage divider comprising first and second resistors R1 and R2, respectively. The first resistor R1 may be configured having a first terminal connected to the drain of the bias transistor M_{BIAS} at node N3, and a second terminal connected to the gate of the feedback transistor MFB at a fourth node, N4. The second resistor R2 may be configured having a first terminal connected to the gate of the feedback transistor MFB at node N4, and a second terminal connected to the second voltage source, which may be a −10 volt supply, although embodiments of the invention are not limited thereto. Optionally, an RF decoupling capacitor C3 may be connected between the second voltage source and ground and configured to shunt signals in the RF frequency range that may be introduced into the second voltage source.

A third resistor, R3, may be connected between the source of the feedback transistor MFB at node N2 and the second voltage source. The feedback transistor MFB is preferably connected in a source follower configuration, which effectively presents a low impedance at the gate of the RF output transistor M_{OUT} at node N2, while presenting a high impedance at the gate of the feedback transistor MFB at node N4 to isolate the gate of the RF output transistor Mour from the voltage divider (resistors R1 and R2, in this embodiment); this represents an improvement over the illustrative biasing circuit 304 shown in FIG. 3.

A resistance value of resistor R3 may be selected to present a prescribed impedance at the gate of the RF output transistor M_{OUT}. The value selected for resistor R3 may be process dependent (e.g., a function of device threshold voltage Vth), but may also depend on the gate width of the biasing transistors and the power supply value (e.g., −10V in this illustrative embodiment), among other factors. By way of example only and without limitation or loss of generality, assuming that the biasing circuit draws milliamperes (mAs) of current, and because a typical biasing voltage (for an exemplary process) may be about-2.7V, an exemplary resistance value for resistor R3 may be selected in a range: 7.3V/(several mA), so about 7K ohms for 1 mA, about 3.5K ohms for 2 mA, and so on.

The feedback transistor MFB may be implemented using a low-impedance FET device. This can be achieved, in one or more embodiments, using a large gate width (GW) for the feedback transistor MFB (e.g., about 500 μm or greater), since the impedance of a FET device (Z_{FET}) is inversely proportional to its gate width (i.e., Z_{FET}˜1/GW). Current consumption in the low-impedance path including the feedback transistor MFB and the resistor R3 will be proportional to the gate width of the feedback transistor MFB. Therefore, a tradeoff exists between impedance and current consumption in the biasing circuit 602. With the drain of the feedback transistor MFB connected to the first voltage source, which may be a high voltage (e.g., 50V) supply, a power FET device (e.g., LDMOS device) is preferably used to implement the feedback transistor; this may be consistent with a desire to employ a large gate width for reducing the impedance of the low-impedance path.

Thus, with continued reference to FIG. 6, a biasing circuit for biasing an output transistor in an RF amplifier, according to one or more embodiments of the invention, includes a first FET (M_{BIAS}) monolithically integrated with the output transistor (M_{OUT}), the first FET including a first source/drain(S) connected to a first voltage source (which may be ground), a gate (G) connected to a gate of the output transistor (M_{OUT}), and a second source/drain (D) connected to a current source (306) configured to supply a prescribed current to the first FET. The bias circuit further includes a voltage divider coupled to the current source and configured to control a voltage at the gate of the first FET for setting a DC quiescent current in the output transistor (M_{OUT}). In some embodiments, the biasing circuit may include: a second FET (MFB) connected in a negative feedback configuration with the first FET (M_{BIAS}), the second FET having a gate connected to the voltage divider, and having a first source/drain(S) connected to the gate of the output transistor (M_{OUT}) in a source follower configuration; and a resistor (R3) connected between the first source/drain of the second FET (MFB) and a second voltage source. In some embodiments, a second source/drain (D) of the second FET (MFB) may be connected to a third voltage source, and the voltage divider may include a first resistor (R1) connected between the gate of the second FET (MFB) and the current source, and a second resistor (R2) connected between the gate of the second FET (MFB) and the second voltage source. In some embodiments, the biasing circuit further comprises a decoupling capacitor connected between the first and second voltage sources, the decoupling capacitor being configured to shunt signals in a prescribed RF frequency range. In some embodiments, the first FET (M_{BIAS}) may be a low-voltage device and the second FET (MFB) may be a high-voltage device. In one or more embodiments, the first source/drain of the first FET (M_{BIAS}) is connected to a first source/drain(S) of the output transistor (M_{OUT}).

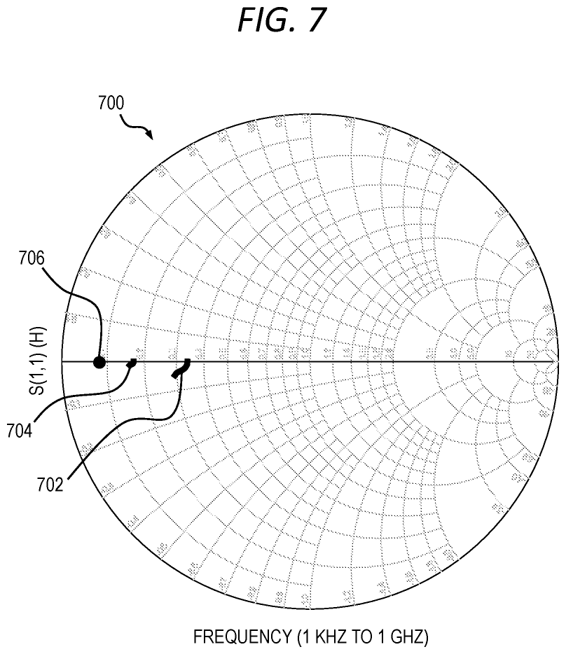

By way of illustration only and without limitation, FIG. 7 is a Smith chart plot 700 graphically depicting exemplary impedance presented at the gate of the output transistor M_{OUT}, in the exemplary RF amplifier 600 of FIG. 6 as a function of frequency. Waveform 702 represents the impedance presented to the gate of the output transistor M_{OUT} using a gate width of 500 μm for the bias transistor M_{BIAS}; waveform 704 represents the impedance presented to the gate of the out transistor M_{OUT} using a gate width of 1000 μm for the bias transistor M_{BIAS}; and waveform 706 represents the impedance presented to the gate of the output transistor M_{OUT} using a gate width of 2000 μm for the bias transistor M_{BIAS}. The current consumption in the low-impedance path of the biasing circuit 602, which includes the feedback transistor MFB and the resistor R3, using a gate width of 500 μm for the feedback transistor MFB is about 5 mA, while the current consumption using a gate width of 1000 μm is about 10 mA and the current consumption using a gate width of 2000 μm is about 20 mA.

As apparent from FIG. 7, the larger the gate width used for the feedback transistor MFB, the closer the impedance presented to the gate of the output transistor M_{OUT} in the output stage 302 is to ideal (zero ohms) and the larger the current consumption is in the low-impedance path. Additionally, as the gate width of the feedback transistor MFB is reduced, the impedance presented to the gate of the output transistor M_{OUT} varies more with frequency. Thus, if current consumption is not an important factor, it may be beneficial to select a gate width that is maximized based on the available chip area; otherwise, a gate width selection for the feedback transistor MFB can be made which provides a satisfactory tradeoff between current consumption in the biasing circuit 602 and impedance presented to the gate of the RF output transistor M_{OUT}.

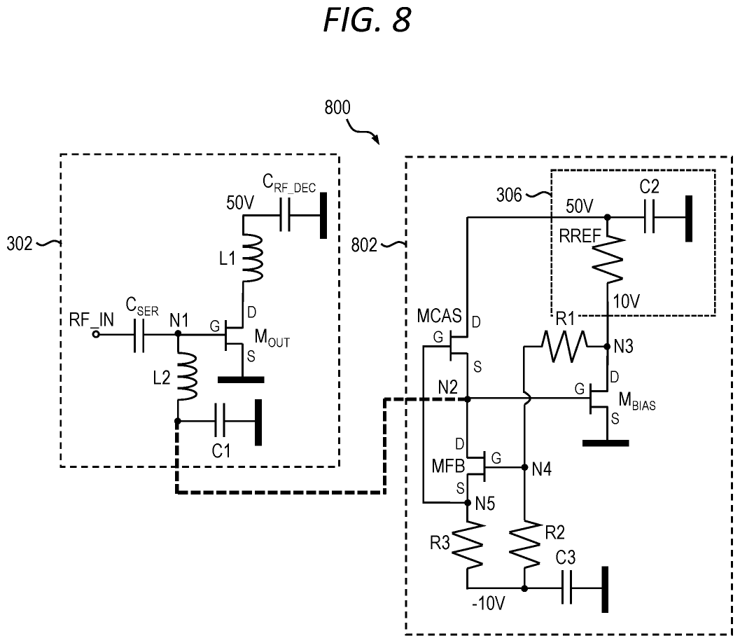

One way to reduce current consumption in the biasing circuit without increasing the impedance presented at the gate of the RF output transistor M_{OUT} is to employ a cascode arrangement in the low-impedance path. By way of example only and without limitation, FIG. 8 is a schematic diagram depicting at least a portion of an exemplary RF amplifier 800 including an active biasing circuit that includes negative feedback and a cascode low-impedance path, according to one or more embodiments of the invention. With reference to FIG. 8, the RF amplifier 800 includes an output stage 302, which may be implemented in the same manner as previously described and shown in FIGS. 3 and 6, and an active biasing circuit 802 configured to be coupled to and monolithically integrated with the output transistor M_{OUT} of the output stage 302.

The biasing circuit 802 may be implemented in a manner similar to the biasing circuit 602 shown in FIG. 6, except for the inclusion of a cascode low-impedance path. Specifically, the biasing circuit 802 includes the bias FET M_{BIAS} having a drain connected to the current source 306 at node N3, and a source connected to ground (or another voltage source, such as VSS). The biasing circuit 802 may further include a cascode low-impedance path connected in a negative feedback configuration with the bias transistor M_{BIAS}. More particularly, the low-impedance path may comprise the feedback transistor MFB connected in a cascode arrangement with a cascode FET, MCAS, connected as a source follower, such that a drain of the FET MCAS is connected to the first voltage source, a source of MCAS is connected to the gate of the bias transistor M_{BIAS} at node N2, a gate of MCAS is connected the source of the feedback transistor MFB at a fifth node, N5, the drain of MFB is connected to the source of MCAS at node N2, and a gate of MFB is connected to the voltage divider at node N4 including the first and second resistors R1 and R2, respectively. As in the biasing circuit 602 of FIG. 6, the first resistor R1 may be connected between the drain of the bias transistor M_{BIAS} at node N3 and the gate of the feedback transistor MFB at node N4, and the second resistor R2 may be connected between the gate of the feedback transistor MFB at node N4 and the second voltage source, which may be a −10 volt supply. Optionally, an RF decoupling capacitor C3 may be connected between the second voltage source and ground and configured to shunt signals in the RF frequency range that may be introduced into the second voltage source. The third resistor R3 may be connected between the source of the feedback transistor MFB at node N5 and the second voltage source.

The cascode transistor MCAS is preferably connected in a source follower configuration with the gate of the bias transistor M_{BIAS}, which effectively presents a low impedance at the gate of the RF output transistor M_{OUT} at node N2. Another benefit of using the cascode arrangement in the low-impedance path is that the high voltage supplied by the first voltage source can be distributed across the drain and source regions of both the feedback transistor MFB and the cascode transistor MCAS, so that the respective sizes of these device may be reduced.

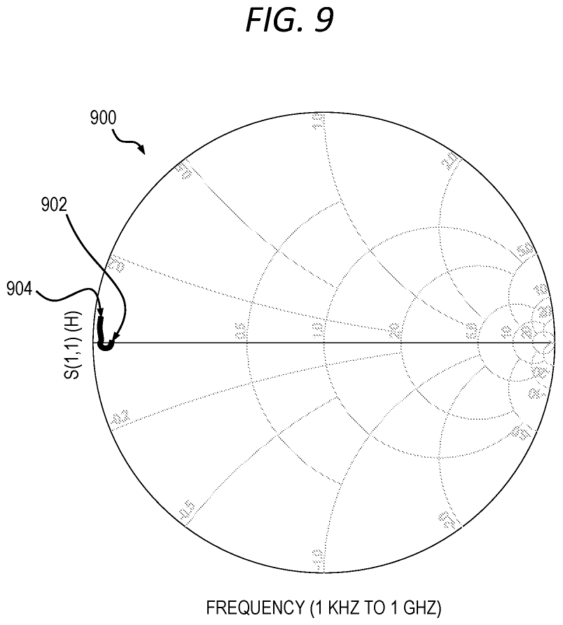

By way of illustration only and without limitation, FIG. 9 is a Smith chart plot 900 graphically depicting the impedance presented to the gate of the RF output transistor M_{OUT} (FIG. 8) as a function of frequency using the illustrative biasing circuit 802 shown in FIG. 8. Exemplary component values for the biasing circuit 802 used in generating the Smith chart plot 900 are provided in the table below; it is also assumed that a load of 50 ohms is presented on the output of the RF amplifier 800 (drain of output transistor M_{OUT}). It is to be understood that embodiments of the invention are not limited to these component values.

| RREF | 26.2K | ohms |
|---|---|---|
| R1 | 178K | ohms |
| R2 | 22.1K | ohms |
| R3 | 388 | ohms |

Data points 902 and 904 on the Smith chart plot 900 represent the impedance presented to the gate of the RF out transistor M_{OUT}, using the cascode biasing circuit 802 of FIG. 8, at 1 KHz and 200 MHz, respectively. As apparent from FIG. 9, the impedance presented to the gate of the RF transistor M_{OUT} using the biasing circuit 802 remains nearly an ideal short circuit (0 ohms) from about 1 KHz to 200 MHz, with a significant reduction in impedance variance with frequency compared to conventional biasing arrangements.

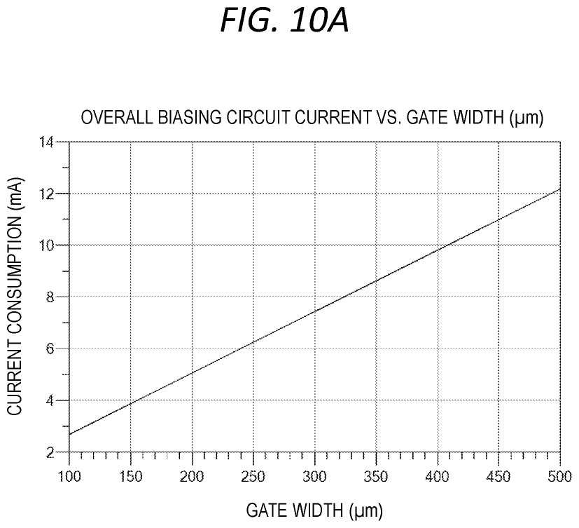

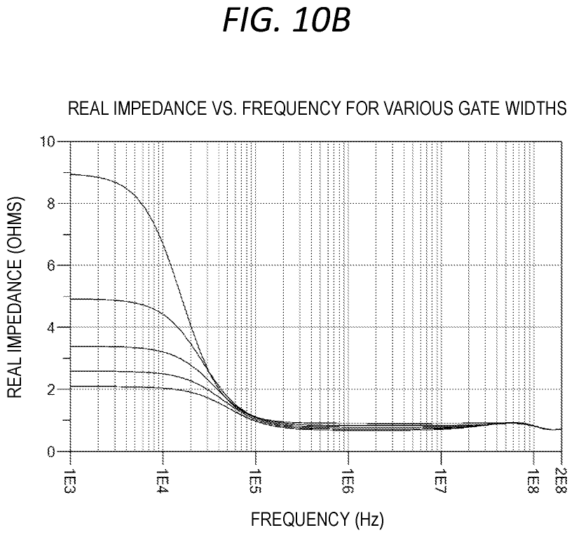

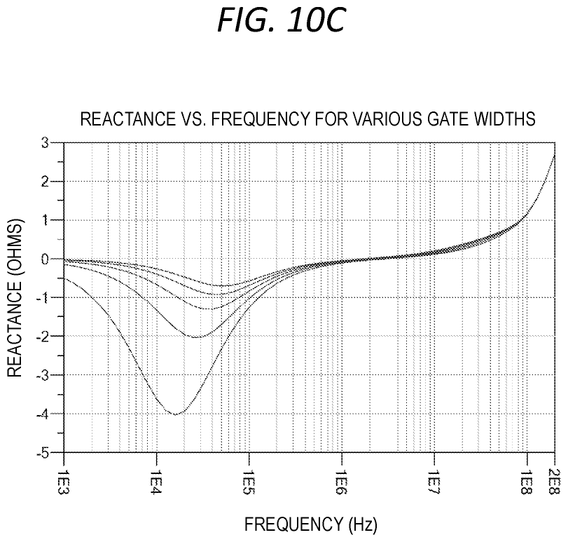

As previously stated, a tradeoff may exist between the gate width used for the transistors in the biasing circuit according to embodiments of the invention and both the current consumption in the biasing circuit and the impedance presented to the RF output transistor to be biased. By way of example only, FIGS. 10A through 10C are graphs conceptually depicting the impact of the gate width of the transistors used in the biasing circuit 802 shown in FIG. 8 on current consumption and real and imaginary baseband impedance presented to the RF output transistor M_{OUT} to be biased. To obtain the waveforms depicted in the graphs, gate width was swept from 2×100 μm to 2×500 μm in steps of 100 μm.

FIG. 10A conceptually shows a linear correlation between transistor gate width and current consumption in the biasing circuit, with current consumption for a gate width of 2×100 μm being about 2.8 mA and the current consumption for a gate width of 2×500 μm being about 12.1 mA.

FIG. 10B conceptually depicts the real impedance (in ohms) presented to the gate of the RF output transistor to be biased as a function of frequency, from 1 KHz to 200 MHz, with each waveform corresponding to a given one of the gate widths from 2×100 μm to 2×500 μm (in steps of 100 μm). Below about 60 KHz, there is a wide variation in real impedance presented to the gate of the RF transistor. For example, at a frequency of 1 KHz, a gate width of 2×100 μm presents a real impedance to the gate of the RF transistor to be biased of about 9 ohms, and a gate width of 2×500 μm presents a real impedance of about 2 ohms. Above about 100 KHz, however, the impedance presented to the gate of the RF transistor seems to converge, regardless of gate width, at about 1 ohm, indicating an impact of the decoupling elements in the amplifier output stage having a more dominant impact on impedance at the RF transistor gate.

FIG. 10C conceptually depicts the imaginary impedance (in ohms) presented to the gate of the RF output transistor to be biased as a function of frequency, from 1 KHz to 200 MHz, with each waveform corresponding to a given one of the gate widths from 2×100 μm to 2×500 μm (in steps of 100 μm). Below about 100 KHz, there is a wide variation in the imaginary impedance (i.e., reactance) presented to the gate of the RF transistor. For example, at a frequency of 20 KHz, a gate width of 2×100 μm presents a reactance to the gate of the RF transistor to be biased of about-4 ohms, and a gate width of 2×500 μm presents a reactance of about-0.5 ohms. Above about 500 KHz, however, the reactance presented to the gate of the RF transistor to be less impacted by gate width of the transistors in the biasing circuit.

As apparent from FIGS. 10A through 10C, in applications where minimizing current consumption in the biasing circuit is an objective, selecting a gate width of about 2×200 μm, in some embodiments, may provide an acceptable compromise: current consumption in the biasing circuit is less than about 5 mA and the impedance presented to the gate of the RF transistor to be biased is below about 5 ohms.

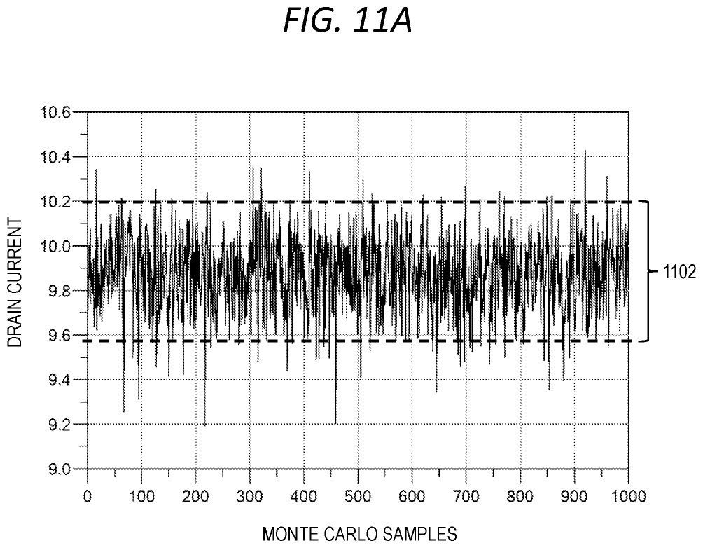

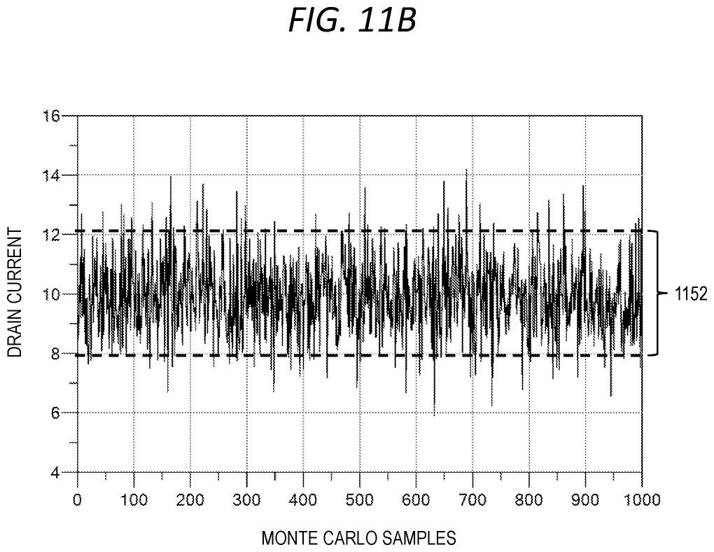

An accuracy of the biasing circuit 802, in terms of drain current of the biasing FET M_{BIAS}, can be predicted using a Monte Carlo simulation based on a sample size of 1000 biasing circuits. FIGS. 11A and 11B are graphs plotting exemplary simulation results showing the variation in drain current of the bias FET M_{BIAS} over 1000 samples; FIG. 11A is a graph depicting the biasing accuracy (in terms of drain current of the bias FET M_{BIAS}) using a tolerance of +10% for the integrated resistors in the biasing circuit 802 (e.g., resistors R1, R2, R3), and FIG. 11B is a graph depicting the biasing accuracy using a pinch-off voltage tolerance of +50 mV for the transistors in the biasing circuit 802. With reference to FIG. 11A, the drain current of the bias FET M_{BIAS} falls primarily in a range 1102 which exhibits a ±3% variation over 1000 samples with a ±10% tolerance for the integrated resistors. In FIG. 11B, the drain current falls primarily within a range 1152 which exhibits a ±20% variation over 1000 samples with a ±50 m V pinch-off voltage tolerance for the transistors in the biasing circuit 802.

As an added benefit, the biasing circuit (e.g., 304 in FIG. 3, 602 in FIG. 6, or 802 in FIG. 8) according to embodiments of the invention may provide ESD protection for the RF transistor to be biased (e.g., MOUT), due primarily to the low impedance presented by the biasing circuit to the gate of RF transistor to be biased. ESD may be defined as a rapid, spontaneous transfer of an electrostatic charge that occurs when two objects at different electrostatic potentials come into contact or otherwise approach one another. A human body model (HBM) is often used to simulate a person becoming charged and discharging from a bare finger to ground through a device or circuit under test.

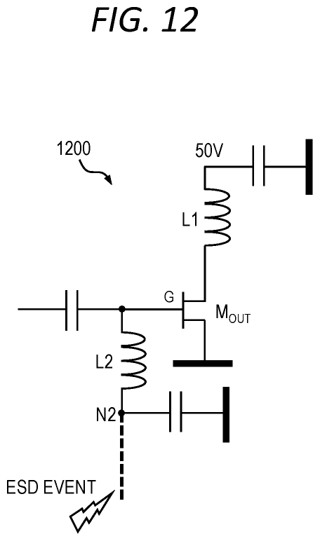

FIG. 12 is a schematic diagram depicting at least a portion of an output stage 1200 of an exemplary RF amplifier without ESD protection. The output stage 1200 may be implemented in manner consistent with the output stage 302 depicted in FIG. 8, although embodiments of the invention are not limited thereto. Without ESD protection, when an ESD event occurs at node N2 of the output stage 1200, the transient ESD spike or pulse will be conveyed through the inductor L2 to the gate of the RF FET M_{OUT}, potentially damaging the FET.

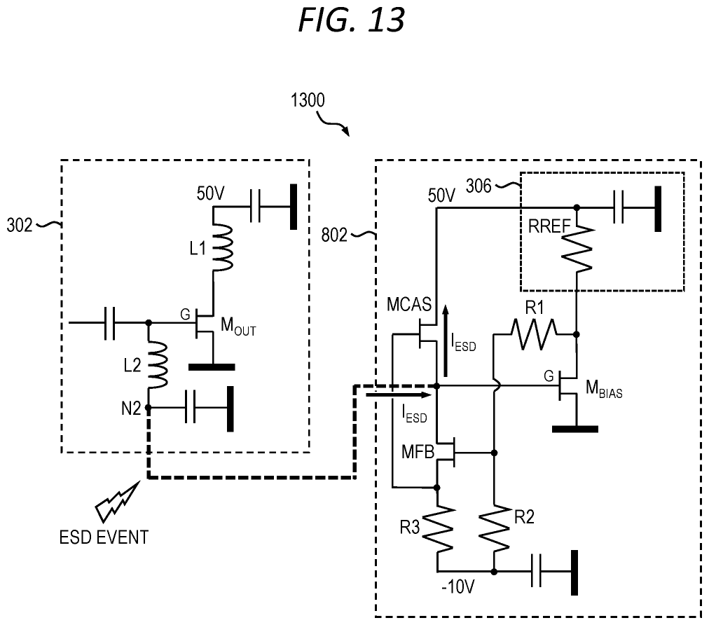

FIG. 13 is a schematic diagram depicting at least a portion of an exemplary RF amplifier 1300 that includes an active biasing circuit configured to provide ESD protection, according to one or more embodiments of the invention. The RF amplifier 1300, which is essentially the same as the RF amplifier 800 shown in FIG. 8, includes an output stage 302 and an active biasing circuit 802 monolithically integrated with the output stage 302. As previously described in conjunction with FIG. 8, the biasing circuit 802 includes a low-impedance path comprising cascode FET MCAS (configured as a source follower), feedback FET MFB, and resistor R3 connected in series between the first voltage source, which may be a 50V supply, and the second source, which may be a −10V supply. Configured in this manner, the biasing circuit 802 is equivalent to a broadband 2-ohm circuit, due primarily to the source follower FET MCAS included in the low-impedance path. When as ESD event occurs at node N2, the ESD spike or pulse will generate a current, I_{ESD}, that is conveyed to the low-impedance path, through the source follower FET MCAS, which is preferably configured to handle the higher voltage and/or current of the ESD event, and is discharged to ground through the first voltage source. Thus, the biasing circuit 802 may, as an added benefit, provide ESD protection for the RF transistor (e.g., M_{OUT}) to be biased.

Embodiments of the present disclosure may be used in various cellular infrastructure (CIFR) RF power products (including, but not limited to 5 W, 10 W, 20 W, 40 W, 60 W, 80 W and different frequency bands) e.g., for fifth-generation technology standard (5G) broadband cellular networks and base station applications, as well as for radar and monolithic microwave integrated circuit (MMIC)-type applications. More generally, any RF amplifier may be used in conjunction with and may benefit from embodiments of the present disclosure.

It will be understood that, although the terms “first,” “second,” etc., may be used herein to describe various elements, these elements should not be limited by such terms. These terms are only used to distinguish one element from another and should not be interpreted as conveying any particular order of the elements with respect to one another. For example, a first element could be termed a second element, and, similarly, a second element could be termed a first element, without departing from the scope of the present disclosure. As may be used herein, the term “and/or” when used in conjunction with an associated list of elements is intended to include any and all combinations of one or more of the associated listed elements. For example, the phrase “A and/or B” is intended to include element A alone, element B alone, or elements A and B.

The terminology used herein is for the purpose of describing particular embodiments of the inventive concepts only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” as used herein, are intended to specify the presence of stated features, integers, steps, operations, elements, and/or components, but do not necessarily preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

In accordance with embodiments of the present disclosure described herein, when an element such as a device or circuit, for example, is referred to as being “connected” or “coupled” to another element, it is to be understood that the element can be directly connected or coupled to the other element or intervening elements may be present. In contrast, when an element is referred to as being “directly connected” or “directly coupled” to another element, it is intended that there are no intervening elements present.

Relative terms such as, for example, “below,” “above,” “upper,” “lower,” “horizontal,” “lateral,” and/or “vertical,” may be used herein to describe a relationship of one element, layer or region to another element, layer or region as illustrated in the figures. It will be understood, however, that these terms are intended to encompass different orientations of a device or structure in place of or in addition to the orientation depicted in the figures.

Like reference numbers and/or labels, as may be used herein, are intended to refer to like elements throughout the several drawings. Thus, the same numbers and/or labels may be described with reference to other drawings even if they are neither explicitly mentioned nor described in the corresponding drawing. Moreover, elements that are not denoted by reference numbers and/or labels may be described with reference to other drawings.

In the drawings and specification, there have been disclosed typical embodiments of the invention and, although specific terms may be employed, they are intended to be used in a generic and descriptive sense only and not for purposes of limitation, the scope of the invention being set forth in the appended claims.

1. A biasing circuit for biasing an output transistor in a radio frequency (RF) amplifier, the biasing circuit comprising:
a first field-effect transistor (FET) monolithically integrated with the output transistor, the first FET including a first source/drain connected to a first voltage source, a gate connected to a gate of the output transistor, and a second source/drain connected to a current source configured to supply a prescribed current to the first FET; and
a voltage divider coupled to the current source and configured to control a voltage at the gate of the first FET for setting a direct current (DC) quiescent current in the output transistor.

2. The biasing circuit according to claim 1, wherein the voltage divider includes a first resistor connected between the second source/drain and the gate of the first FET, and a second resistor connected between the gate of the first FET and a second voltage source.

3. The biasing circuit according to claim 2, wherein the first and second resistors are formed of the same material and are disposed proximate to one another.

4. The biasing circuit according to claim 1, further comprising:
a second FET connected in a negative feedback configuration with the first FET, the second FET having a gate connected to the voltage divider, and having a first source/drain connected to the gate of the output transistor in a source follower configuration; and
a resistor connected between the first source/drain of the second FET and a second voltage source.

5. The biasing circuit according to claim 4, wherein a second source/drain of the second FET is connected to a third voltage source, and wherein the voltage divider includes a first resistor connected between the gate of the second FET and the current source, and a second resistor connected between the gate of the second FET and the second voltage source.

6. The biasing circuit according to claim 4, further comprising a decoupling capacitor connected between the first and second voltage sources, the decoupling capacitor being configured to shunt signals in a prescribed RF frequency range.

7. The biasing circuit according to claim 4, wherein the first FET is a low-voltage device and the second FET is a high-voltage device.

8. The biasing circuit according to claim 1, further comprising:
a second FET having a gate connected to the voltage divider, and having a first source/drain connected to a second voltage source through a third resistor; and
a third FET having a first source/drain connected to a second source/drain of the second FET in a cascode configuration and connected to the gate of the first FET in a source follower configuration, a gate connected to the first source/drain of the second FET, and a second source/drain connected to a third voltage source.

9. The biasing circuit according to claim 8, wherein the voltage divider comprises a first resistor connected between the gate of the second FET and the current source, and a second resistor connected between the gate of the second FET and the second voltage source.

10. The biasing circuit according to claim 8, further comprising a decoupling capacitor connected between the first and second voltage sources, the decoupling capacitor being configured to shunt signals in a prescribed RF frequency range.

11. The biasing circuit according to claim 8, wherein each of the first and second FETs is a low-voltage device, and the third FET is a high-voltage device.

12. The biasing circuit according to claim 1, wherein an impedance presented to the gate of the output transistor by the biasing circuit is configured to be about 0 to 10 ohms per millimeter of gate width of the output transistor.

13. The biasing circuit according to claim 1, wherein the gate of the first FET is connected to the gate of the output transistor in the RF amplifier through a series inductor.

14. The biasing circuit according to claim 1, wherein the current source comprises:
an external resistor connected between the voltage divider and a third voltage source; and
a decoupling capacitor connected between the first and third voltage sources, the decoupling capacitor being configured to shunt signals in a prescribed RF frequency range.

15. The biasing circuit according to claim 1, wherein the first FET is formed as at least one finger among a plurality of fingers of the output transistor.

16. The biasing circuit according to claim 1, wherein the first source/drain of the first FET is connected to a first source/drain of the output transistor, such that the first FET and the output transistor are connected together in a current mirror configuration.

17. A biasing circuit for biasing an output transistor in a radio frequency (RF) amplifier, the biasing circuit comprising:
a first field-effect transistor (FET) monolithically integrated with the output transistor, the first FET being connected to the output transistor in a current mirror configuration, such that a gate-to-source voltage of the first FET is the same as a gate-to-source voltage of the output transistor, and a drain current in the first FET is matched to a drain current in the output transistor and scaled proportionally according to a size of the first FET relative to a size of the output transistor; and
a voltage divider integrated with the first FET and connected to a current source, the voltage divider being configured to generate a voltage that is substantially independent of temperature variations for controlling the drain current in the first FET.

18. The biasing circuit according to claim 17, wherein the first FET includes a first source/drain connected to a first voltage source, a gate connected to a gate of the output transistor, and a second source/drain connected to the current source.

19. The biasing circuit according to claim 18, wherein the voltage divider includes a first resistor connected between the second source/drain and the gate of the first FET, and a second resistor connected between the gate of the first FET and a second voltage source.

20. (canceled)

21. The biasing circuit according to claim 17, further comprising:
a second FET connected in a negative feedback configuration with the first FET, the second FET having a gate connected to the voltage divider, and having a first source/drain connected to a gate of the output transistor in a source follower configuration; and
a third resistor connected between the first source/drain of the second FET and a second voltage source.

22.-24. (canceled)

25. The biasing circuit according to claim 17, further comprising:
a second FET having a gate connected to the voltage divider, and having a first source/drain connected to a second voltage source through a third resistor; and
a third FET having a first source/drain connected to a second source/drain of the second FET in a cascode configuration and connected to a gate of the first FET in a source follower configuration, a gate connected to the first source/drain of the second FET, and a second source/drain connected to a third voltage source.

26.-28. (canceled)

29. The biasing circuit according to claim 17, wherein an impedance presented to the gate of the output transistor by the biasing circuit is configured to be about 0 to 10 ohms per millimeter of gate width of the output transistor.

30. (canceled)

31. The biasing circuit according to claim 17, wherein the current source comprises:
an external resistor connected between the voltage divider and a third voltage source; and
a decoupling capacitor connected between the first and third voltage sources, the decoupling capacitor being configured to shunt signals in a prescribed RF frequency range.

32. (canceled)

33. A biasing circuit for biasing an output transistor in a radio frequency (RF) amplifier, the biasing circuit comprising:
a first field-effect transistor (FET) monolithically integrated with the output transistor, the first FET being connected to the output transistor in a current mirror configuration, such that a drain current in the first FET is matched to a drain current in the output transistor and scaled proportionally according to a size of the first FET relative to a size of the output transistor;
wherein the biasing circuit is configured such that a current in the first FET is substantially independent of process, voltage and/or temperature variations, and wherein an impedance presented to a gate of the output transistor by the biasing circuit is configured to be about 0 to 10 ohms per millimeter of gate width of the output transistor.
